(19) United States
(12) Patent Application Publication
(10) Pub. No.: US 2011/0100424 A1
(43) Pub. Date: May 5, 2011

(54) TRANSPARENT SUBSTRATE WITH ANTI-REFLECTION COATING

(75) Inventors: Stephanie Roche, Paris (FR); Erwan Mahe, Orvault (FR); Laurent Labrousse, Annonay (FR)

(73) Assignee: SAINT-GOBAIN GLASS FRANCE, Courbevoie (FR)

(21) Appl. No.: 12/921,898

(22) PCT Filed: Mar. 10, 2009
(86) PCT No.: PCT/FR2009/050387

§ 371 Date: Dec. 7, 2010

(30) Foreign Application Priority Data
Mar. 10, 2008 (FR) 0851510

(51) Int. Cl. H01L 31/052; C23C 14/34; G02B 1/11; H01L 31/18

(52) U.S. Cl. 136/246; 204/192.1; 359/586; 359/350; 438/67; 257/E31.11

(57) ABSTRACT

The subject of the invention is a transparent substrate (6), especially glass substrate, comprising an antireflection coating on at least one of its faces, which is made of a multilayer (A) of thin layers having alternately high and low refractive indices.

The multilayer is characterized in that the high-index first layer (1) and/or the high-index third layer (3) are based on a zinc tin mixed oxide, with a ratio, expressed in atomic percent, of the tin to the zinc that is greater than 1.

The invention relates to a transparent substrate, especially a glass substrate, provided on at least one of its faces with an antireflection coating.

Antireflection coatings usually consist, in the simplest cases, of a thin interference layer whose refractive index is between that of the substrate and that of air or, in more complex cases, of a multilayer of thin layers (in general, an alternation of layers based on dielectric materials having high and low refractive indices).

In their most conventional applications, they are used to reduce the light reflection from substrates in order to increase the light transmission thereof. Such substrates are, for example, glazing intended for protecting paintings or for producing shop counters or windows. They are therefore optimized by only taking into account the wavelengths in the visible range.

However, it has emerged that there may be a need to increase the transmission of transparent substrates for special applications, and not only in the visible range.

It is known that elements capable of collecting light of the photovoltaic solar cell type comprise an absorbent agent that provides the conversion of the light to electrical energy.

Ternary chalcopyrite compounds, which may act as absorber, generally contain copper, indium and selenium. These are referred to as CISe₂ absorbent agent layers. The layer of absorbent agent may also contain gallium (e.g. Cu(In,Ga)Se₂ or CuGaSe₂), aluminum (e.g. Cu(In,Al)Se₂), or sulfur (e.g. CuIn(Se,S). They are denoted in general, and hereafter, by the term chalcopyrite absorbent agent layers.

Another family of absorbent agents, as a thin layer, is either based on silicon, which may be amorphous or microcrystalline, or based on cadmium telluride (CdTe). There also exists another family of absorbent agents based on polycrystalline silicon wafers, deposited as a thick layer, with a thickness between 50 μm and 250 μm, unlike the amorphous or microcrystalline silicon system, which is deposited as a thin layer.

For these absorbent agents of various technologies, it is known that their photovoltaic efficiency (energy conversion) is appreciably reduced if the light transmission over the whole of the spectrum is not maximized.

It therefore appears advantageous, in order to increase their efficiency, to optimize the transmission of solar energy through this glass in the wavelengths that are important for solar cells.

A first solution has consisted in using extra-clear glass having a low content of iron oxide(s). This may be, for example, glass sold in the “DIAMANT” range by Saint-Gobain Glass or glass sold in the “ALBARINO” range by Saint-Gobain Glass.

Another solution has consisted in providing the glass, on the outer side, with an antireflection coating made from a monolayer of porous silicon oxide, the porosity of the material allowing the refractive index thereof to be lowered. However, the performance of this single-layer coating is not very high. It is also insufficiently durable, especially with regard to moisture.

Another solution has consisted in providing the glass, on the outer side, with an antireflection coating of thin layers made of dielectric materials with alternately high and low refractive indices, such as those described in applications WO 01/94989 and WO 04/05210.

Nevertheless, it is apparent that the antireflection coatings of this type for which the layers having a high refractive index are based on a zinc tin mixed oxide and for which the layers having a low refractive index are based on silicon dioxide have the major disadvantage of debonding from the substrate when they are tempered under certain conditions and exposed to certain climatic conditions (in particular high relative humidity).

This detrimental phenomenon has been more particularly observed for multilayers for which all the high-index layers were based on Zn₇₅Sn₂₅O (expressed in percent by weight), Zn_{0.85}Sn_{0.15}O (expressed in atomic percent), or Zn₅₀Sn₅₀O (expressed in percent by weight) or Zn_{0.65}Sn_{0.35}O (expressed in atomic percent).

It has also been observed that an oxide of Zn₁₀₀Sn₀O (expressed in percent by weight) did not have any hydrolytic resistance and that, on the other hand, ZnₒSn₁₀₀O (expressed in percent by weight) did have this property.

From this observation and by also taking into account that under the effect of a heat treatment, a mixed oxide of SnZnO (denoted by SnZnOₓ) remained amorphous whereas, taken separately, SnO₂ and ZnO, under this same heat treatment, have a tendency to crystallize, the inventors have surprisingly and unexpectedly discovered that a particular mixed oxide composition, as a high refractive index material of the layers of an antireflection multilayer (the layers having a low refractive index being made of SiO₂) made it possible to obtain a multilayer that was very robust after heat treatment, offering, in addition, the advantage of being not very absorbent in the range of wavelengths between the ultraviolet spectrum and the blue spectrum, in which range silicon-based solar cells have part of their energy conversion efficiency peak.

The objective of the invention is in that case the development of a novel antireflection coating which is mechanically robust, regardless of the heat treatment conditions, and which is capable of further increasing the transmission (of further reducing the reflection) through the transparent substrate that bears it, in a broad band of wavelengths, especially in the visible spectrum, in the infrared spectrum or even in the ultraviolet spectrum simultaneously.

In addition, an objective of the invention is the development of a novel antireflection coating suitable for solar cells.

In addition, an objective of the invention is the development of such coatings which are also capable of undergoing heat treatments, especially in the case where the carrier substrate is made of glass which, in its final application must be annealed or tempered.

In addition, an objective of the invention is the development of such coatings which are sufficiently durable for outside use.

Therefore, one subject of the invention is firstly a transparent substrate, especially glass substrate, comprising an antireflection coating, in particular that is antireflective at least in the visible and in the near infrared, on at least one of its faces, made from a multilayer of thin layers made of dielectric materials with alternately high and low refractive indices, the multilayer comprising, in succession:
a high-index first layer having a refractive index n₁ at 550 nm of between 1.8 and 2.3 and a geometrical thickness e₁ of between 15 and 35 nm;
a low-index second layer having a refractive index n₂ at 550 nm of between 1.30 and 1.70 and a geometrical thickness e₂ of between 15 and 35 nm;
a high-index third layer having a refractive index n₃ at 550 nm of between 1.8 and 2.3 and a geometrical thickness e₃ of between 130 and 160 nm;
a low-index fourth layer having a refractive index n₄ at 550 nm of between 1.30 and 1.70 and a geometrical thickness e₄ of between 80 and 110 nm;
   the low-index second layer and/or the low-index fourth layer being based on silicon oxide, silicon oxynitride and/or oxycarbide or on a mixed silicon aluminum oxide, and in which
   the high-index first layer and/or the high-index third layer (3) is (are) based on a zinc tin mixed oxide, with a ratio, expressed in atomic percent, of the tin to the zinc that is greater than 1, or based on silicon nitride.

Within the context of the invention, the term “layer” is understood to mean either a single layer, or a superposition of layers where each of them respects the refractive index indicated and where the sum of their geometrical thicknesses also remains the value indicated for the layer in question.

Within the meaning of the invention, the layers are made of dielectric material, especially of oxide or nitride type, as will be explained in detail later. However, it is not excluded for at least one of them to be modified so as to be at least slightly conductive, for example by doping a metal oxide, this being done for example, in order possibly to also give the anti-reflection multilayer an antistatic function.

The invention preferentially concerns glass substrates, but may also be applied to transparent polymer-based substrates, for example made of polycarbonate.

The invention therefore relates to a four-layer type antireflection multilayer. This is a good compromise, as the number of layers is large enough for their interference interaction to allow a significant anti-reflection effect to be achieved. However, this number remains sufficiently reasonable for it to be possible to manufacture the product on a large scale, on an industrial line, on large substrates, for example by using a vacuum deposition technique of the magnetically enhanced (magnetron) sputtering type.

The criteria of choice of composition in the material forming the high refractive index layers used in the invention make it possible to obtain a broadband, robust, antireflection effect with a substantial increase in the transmission of the carrier substrate, not only in the visible range but also beyond it, from the ultraviolet up to the near infrared. This is a high-performance antireflection over a wavelength range extending at least between 300 and 1200 nm.

The most suitable materials for making up the first and/or the third layer, those having a high index, are based on metal oxide(s) chosen from zinc oxide ZnO and tin oxide SnO₂. It may especially be a mixed Zn/Sn oxide, of the zinc stannate type, and in an Sn/Zn ratio (expressed in atomic percent) that is greater than 1. They may also be based on silicon nitride(s) Si₃N₄. Using a nitride layer for one or other of the high-index layers, especially the third one at least, makes it possible to add a functionality to the multilayer, namely an ability to better withstand heat treatments without significantly impairing its optical properties for thicknesses of less than 100 nm. However, it is a functionality that is important for the glass which has to form part of the solar cells, as this glass must generally undergo a high-temperature, tempering type, heat treatment where the glass must be heated between 500 and 700° C. It then becomes advantageous to be able to deposit the thin layers before the heat treatment without this causing a problem, because it is simpler from the industrial standpoint for the depositions to be carried out before any heat treatment. It is thus possible to have a single configuration of the antireflection multilayer, whether or not the carrier glass is intended to undergo a heat treatment.

According to another embodiment, the first and/or the third layer, those having a high index, may in fact be made of several superposed high-index layers. This may most particularly be an SnZnO/Si₃N₄ or Si₃N₄/SnZnO type bilayer. Thus, according to the invention, the high-index first layer and/or the high-index third layer may be made exclusively of a zinc tin mixed oxide or of a bilayer of the aforementioned type, with a ratio, expressed in atomic percent, of the tin to the zinc that is greater than 1.

The advantage of this is the following: the Si₃N₄ is substantially less absorbent than the zinc tin mixed oxide, which makes it possible, at an identical total thickness, to combine both the advantages of robustness of the multilayer and optical properties. For the third layer in particular, which is the thickest and the most important for protecting the multilayer from possible deterioration resulting from a heat treatment, it may be beneficial to divide the layer in two so as to put down just the thickness of Si₃N₄ sufficient to obtain the protective effect with regard to the desired heat treatments, and to “top up” the layer optically with a zinc tin mixed oxide of the zinc stannate type.

The most suitable materials for making up the second and/or the fourth layer, those having a low index, are based on silicon oxide, silicon oxynitride and/or silicon oxycarbide or else based on a silicon aluminum mixed oxide. Such a mixed oxide tends to have a better durability, especially chemical durability, than pure SiO₂ (an example of this is given in patent EP 791 562). The respective proportion of the two oxides may be adjusted in order to obtain the expected improvement in durability without excessively increasing the refractive index of the layer.

The glass chosen for the coated substrate of the multilayer according to the invention, or for the other substrates with which it is associated in order to form glazing, may in particular be, for example, “DIAMANT” type extra-clear glass (low in iron oxides in particular), or, for example, be an “ALBARINO” type extra-clear rolled glass or a “PLANILUX” type standard soda-lime-silica clear glass (all three types of glass are sold by Saint-Gobain Vitrage).

Particularly beneficial examples of the coatings according to the invention comprise the following sequences of layers:

for a four-layer multilayer:
SnZnOₓ/SiO₂/SnZnOₓ/SiO₂, with Sn/Zn>1 expressed in atomic percent;
SnZnOₓ/SiO₂/Si₃N₄+SnZnOₓ/SiO₂ with Sn/Zn>1 expressed in atomic percent;
SnZnOₓ/SiO₂/SnZnOₓ+Si₃N₄/SiO₂ with Sn/Zn>1 expressed in atomic percent.

Glass-type substrates, especially extra-clear glass, having this type of multilayer may thus achieve integrated transmission values of at least 90% between 300 and 1200 nm, especially for thicknesses between 2 mm and 8 mm.

Another subject of the invention is the coated substrates according to the invention as outer substrates for solar cells of the type having an absorbent agent based on Si or on CdTe or a chalcopyrite agent (CIS in particular).

This type of product is generally sold in the form of solar cells mounted in series and placed between two glass-type transparent rigid substrates. The cells are held between the substrates by a polymer material (or several polymer materials). According to a preferred embodiment of the invention that is described in patent EP 0 739 042, the solar cells may be placed between the two substrates, then the hollow space between the substrates is filled with a cast polymer capable of curing, most particularly based on polyurethane derived from the reaction of an aliphatic isocyanate prepolymer and a polyether polyol. The polymer may be cured hot (at 30 to 50° C.) and possibly at a slight overpressure, for example in an autoclave. Other polymers may be used, such as ethylene/vinyl acetate EVA, and other arrangements are possible (for example, one or more sheets of thermoplastic polymer may be laminated between the two glass panels of the cells).

It is the combination of the substrates, the polymer and the solar cells that is referred to and sold as a “solar module”.

Another subject of the invention is therefore said modules. With the substrate modified according to the invention, the solar modules may increase their efficiency by a few percent, at least 1, 1.5 or 2%, or even more (expressed as integrated current density) relative to modules using the same substrate but without the coating. When it is known that the solar modules are not sold by the square meter, but by the electrical power delivered (approximately, it may be estimated that one square meter of solar cell may supply about 130 watts), each additional percent of efficiency increases the electrical performance, and therefore the price, of a solar module of given dimensions.

Another subject of the invention is a process for manufacturing glass substrates having an antireflection coating (A) according to the invention. A method consists in depositing all the layers, successively, by a vacuum technique, especially by magnetron sputtering or corona discharge. Thus, it is possible to deposit the oxide layers by reactive sputtering of the metal in question in the presence of oxygen, and the nitride layers in the presence of nitrogen. To make SiO₂ or the Si₃N₄, it is possible to start from a silicon target that is lightly doped with a metal such as aluminum in order to make it sufficiently conductive. For the layers based on a zinc tin mixed oxide, in the presence of oxygen it is possible to use a method of co-sputtering of targets respectively made of zinc and of tin, or a method of sputtering a target based on the desired mixture of tin and zinc, always in the presence of oxygen.

It is also possible, as recommended in patent WO 97/43224, for some of the layers of the multilayer to be deposited by a CVD type hot deposition technique, the rest of the multilayer being deposited cold by sputtering.

The details and advantageous features of the invention will now become apparent from the following nonlimiting examples, with the aid of the figures:

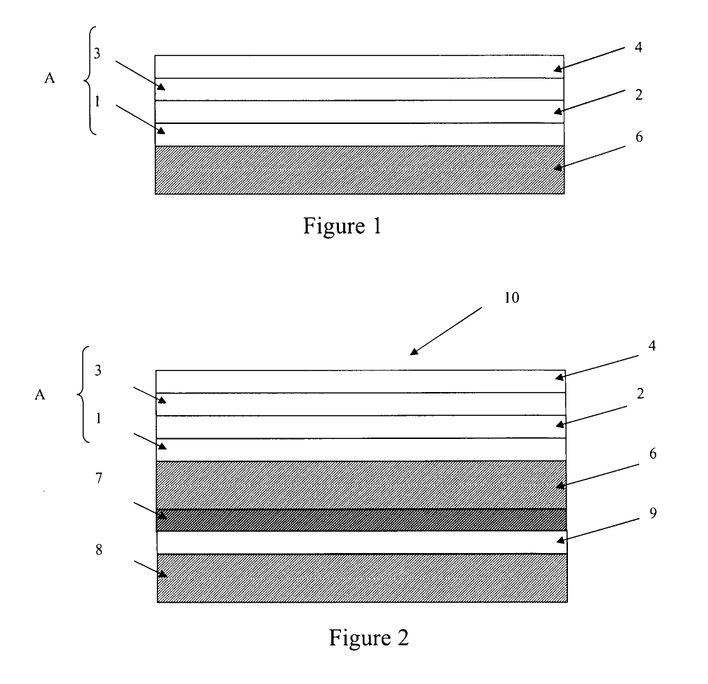

FIG. 1: a substrate provided with a four-layer antireflection multilayer A according to the invention;

FIG. 2: a solar module integrating the substrate according to FIG. 1.

FIG. 1, which is highly schematic, represents, in cross section, a glass 6 surmounted by an antireflection coating (A), having four layers, 1, 2, 3, 4.

### EXAMPLE 1

In this example, the antireflection multilayer used was the following:

| | | Refractive | Example 1 |
|---|---|---|---|
| | | index | (nm) |
| Si₃N₄ | (1) | 1.95-2.05 | 19 |
| SiO₂ | (2) | 1.47 | 29 |
| Si₃N₄ | (3) | 1.95-2.05 | 150 |
| SiO₂ | (4) | 1.47 | 100 |

This example 1 constitutes a first example from the prior art.

### EXAMPLE 2

In this example, the antireflection multilayer used was the following:

| | | Refractive | Example 2 |
|---|---|---|---|
| | | index | (nm) |
| Sn₁₆Zn₈₄Oₓ | (1) | 1.95-2.05 | 19 |
| SiO₂ | (2) | 1.47 | 29 |
| Sn₁₆Zn₈₄Oₓ | (3) | 1.95-2.05 | 150 |
| SiO₂ | (4) | 1.47 | 100 |

This example 2 constitutes a second example from the prior art with an Sn/Zn ratio (expressed in atomic percent) equal to 0.18.

### EXAMPLE 3

In this example, the antireflection multilayer used was the following:

| | | Refractive | Example 3 |
|---|---|---|---|
| | | index | (nm) |
| Sn₃₆Zn₆₄Oₓ | (1) | 1.95-2.05 | 19 |
| SiO₂ | (2) | 1.47 | 29 |
| Si₃N₄ | (3) | 1.95-2.05 | 150 |
| SiO₂ | (4) | 1.47 | 100 |

This example 3 constitutes a third example from the prior art with an Sn/Zn ratio (expressed in atomic percent) equal to 0.55.

The four-layer antireflection multilayer from these examples was deposited onto a substrate 6 made of extra-clear glass having a thickness of 4 mm from the aforementioned DIAMANT range.

Examples 4, 5, 6 are examples according to the invention.

### EXAMPLE 4

In this example, the antireflection multilayer used was the following:

| | | Refractive | Example 4 |
|---|---|---|---|
| | | index | (nm) |
| Sn₆₂Zn₃₈Oₓ | (1) | 1.95-2.05 | 19 |
| SiO₂ | (2) | 1.47 | 29 |
| Sn₆₂Zn₃₈Oₓ | (3) | 1.95-2.05 | 150 |
| SiO₂ | (4) | 1.47 | 100 |

This example 4 constitutes an example according to the invention with an Sn/Zn ratio (expressed in atomic percent) equal to 1.65.

### EXAMPLE 5

In this example, the antireflection multilayer used was the following:

| | | Refractive | Example 5 |
|---|---|---|---|
| | | index | (nm) |
| Sn₆₂Zn₃₈Oₓ | (1) | 1.95-2.05 | 19 |
| SiO₂ | (2) | 1.47 | 29 |
| Si₃N₄ + Sn₆₂Zn₃₈Oₓ | (3) | 1.95-2.05 | 150 |
| SiO₂ | (4) | 1.47 | 100 |

This example 5 constitutes another example according to the invention with an Sn/Zn ratio (expressed in atomic percent) equal to 1.65. The third layer was a bilayer comprising a layer of silicon nitride coated with a zinc tin mixed oxide layer in accordance with the Sn/Zn ratio expressed previously.

### EXAMPLE 6

In this example, the antireflection multilayer used was the following:

| | | Refractive | Example 6 |
|---|---|---|---|
| | | index | (nm) |
| Sn₆₂Zn₃₈Oₓ | (1) | 1.95-2.05 | 19 |
| SiO₂ | (2) | 1.47 | 29 |
| Sn₆₂Zn₃₈Oₓ + Si₃N₄ | (3) | 1.95-2.05 | 150 |
| SiO₂ | (4) | 1.47 | 100 |

This example 6 again constitutes another example according to the invention with an Sn/Zn ratio (expressed in atomic percent) equal to 1.65. The third layer was a bilayer comprising a layer of zinc tin mixed oxide in accordance with the Sn/Zn ratio expressed previously coated with a coated silicon nitride layer.

For examples 5 and 6, the layer (3) comprised 100 nm of SnZnO and 50 nm of Si₃N₄.

Given below is a summary table that gives, for the six examples, the results of the HH test, after heat treatment (tempering for example).

| | HH test (photovoltaic |
|---|---|
| Example number | standard) |
| 1 | N OK |
| 2 | N OK |
| 3 | N OK |
| 4 | OK |
| 5 | OK |
| 6 | OK |

Given below is the description of the HH test.

This test is a test of resistance to humid heat. It makes it possible to determine whether the sample is capable of withstanding the effects of long-term moisture penetration.

The following severe conditions were applied:
test temperature: 85° C.±2° C.;
relative humidity: 85%±5%;
test duration: 1000 h.

Validity conditions of the test:

No appearance of major visual defects should be detected after the test. The sample is then declared to conform (OK).

Another test for validating the examples consists in subjecting the glass having a layer to a neutral saline humid atmosphere (EN 1086 standard) at constant temperature. The neutral saline solution is obtained by dissolving NaCl in demineralized water having a conductivity of less than 30 μs in order to obtain a concentration of 50 g/l (±5 g/l) at 25° C. (±2° C.). The test duration is 21 days. As before, any appearance of major visual defects should not be detected after the test.

The glasses coated with an antireflection coating according to examples 4, 5, 6 are mounted as the outer glass of solar modules. FIG. 2 represents, highly schematically, a solar module 10 according to the invention. The module 10 is formed in the following way: the glass 6 provided with the antireflection coating (A) is combined with a glass 8 known as the “INNER” glass. This glass 8 is made of tempered glass, having a thickness of 4 mm, and of the clear/extra-clear type (Planidur DIAMANT). The solar cells 9 are placed between the two glass panels, then a polyurethane-based curable polymer 7 is poured into the inter-glass space in accordance with the aforementioned teaching of patent EP 0 739 042.

Each solar cell 9 is made, in a known manner, from silicon “wafers” that form a p-n junction and printed front and back electrical contacts. The silicon solar cells may be replaced by solar cells that use other semiconductors (such as based on a chalcopyrite agent of the type, for example, based on CIS, CdTe, a-Si, GaAs, GaInP).

The present substrate constitutes an improvement to the inventions described in international patent applications WO0003209 and WO0194989 which relate to antireflection coatings suitable for optimizing the antireflection effect at non-normal incidence in the visible range (especially targeting applications for vehicle windshields). The features (nature of the layers, index, thickness) are indeed close to those described previously. Advantageously, the coatings according to the present invention have however layers whose thicknesses are reduced and in particular chosen for an advantageous application in the field of solar modules. In particular, a thicker third layer (generally of at least 120 nm and not of at most 120 nm) whose composition, in particular an Sn/Zn ratio of the zinc tin mixed oxide, expressed in atomic percent, of greater than 1, makes it possible to obtain more robust multilayers. Thus, by this particular selection, it becomes possible to obtain layers which do not delaminate over time, even after having undergone a tempering operation.

1. A transparent substrate, comprising an antireflection coating, which is antireflective at least in the visible and in the near infrared, on at least one face, the coating comprising a multilayer (A) of thin layers comprising a dielectric material with alternately high and low refractive indices, the multilayer comprising, in succession:
a high-index first layer having a refractive index n₁ at 550 nm of between 1.8 and 2.3 and a geometrical thickness e₁ of between 15 and 35 nm;
a low-index second layer having a refractive index n₂ at 550 nm of between 1.30 and 1.70 and a geometrical thickness e₂ of between 15 and 35 nm;
a high-index third layer having a refractive index n₃ at 550 nm of between 1.8 and 2.3 and a geometrical thickness e₃ of between 130 and 160 nm;
a low-index fourth layer having a refractive index n₄ at 550 nm of between 1.30 and 1.70 and a geometrical thickness e₄ of between 80 and 110 nm,
wherein
the low-index second layer and/or the low-index fourth layer comprise silicon oxide, silicon oxynitride, and/or oxycarbide, or a mixed silicon aluminum oxide, and
the high-index first layer and/or the high-index third layer comprise a zinc tin mixed oxide, with a ratio, expressed in atomic percent, of tin to zinc that is greater than 1.

2. The substrate as claimed in claim 1, wherein said substrate comprises clear or extra-clear glass.

3. The substrate as claimed in claim 1, wherein the multilayer (A) comprises a sequence of layers as below:
SnZnOₓ, or Si₃N₄/SiO₂/SnZnOₓ, or Si₃N₄/SiO₂,
with Sn/Zn>1, expressed in atomic percent.

4. The substrate as claimed in claim 1, wherein the high-index first layer and/or the high-index third layer comprise a bilayer of Si₃N₄/SnZnOₓ or SnZnOₓ/Si₃N₄.

5. The substrate as claimed in claim 1, wherein the multilayer (A) comprises a sequence of layers as below:
SnZnOₓ/SiO₂/Si₃N₄/SnZnOₓ/SiO₂
with Sn/Zn>1, expressed in atomic percent.

6. The substrate as claimed in claim 1, wherein the multilayer (A) comprises a sequence of layers as below:
SnZnOₓ/SiO₂/SnZnOₓ/Si₃N₄/SiO₂
with Sn/Zn>1, expressed in atomic percent.

7. The substrate as claimed in claim 1, wherein it has an integrated transmission of at least 90% over a wavelength range between 300 and 1200 nm.

8. A process for manufacturing a transparent outer substrate comprising: affixing the substrate as claimed in claim 1 to an outer surface of a solar module comprising a plurality of solar cells comprising an absorbent agent comprising Si or CdTe or chalcopyrite.

9. A solar module comprising a plurality of solar cells of the comprising Si, CIS, CdTe, a-Si, GaAs or GaInP wherein it has, as the outer substrate, the substrate as claimed in claim 1.

10. The solar module as claimed in claim 9, having an increase in its efficiency, expressed as integrated current density, of at least 1% relative to a module that employs an outer substrate but does not have the antireflection multilayer (A).

11. The solar module as claimed in claim 9, comprising two glass substrates; and solar cells placed in an inter-glass space into which a curable polymer has been poured.

12. A process for obtaining the substrate as claimed in claim 1, wherein the antireflection multilayer (A) is deposited by sputtering.

13. The substrate as claimed in claim 2, wherein the glass is toughened or tempered.

14. The substrate as claimed in claim 2, wherein the multilayer (A) comprises a sequence of layers as below:
SnZnOₓ, or Si₃N₄/SiO₂/SnZnOₓ, or Si₃N₄/SiO₂,
with Sn/Zn>1, expressed in atomic percent.

15. The substrate as claimed in claim 13, wherein the multilayer (A) comprises a sequence of layers as below:
SnZnOₓ, or Si₃N₄/SiO₂/SnZnOₓ, or Si₃N₄/SiO₂,
with Sn/Zn>1, expressed in atomic percent.

16. The substrate as claimed in claim 2, wherein the high-index first layer and/or the high-index third layer comprise a bilayer of Si₃N₄/SnZnOₓ or SnZnOₓ/Si₃N₄.

17. The substrate as claimed in claim 13, wherein the high-index first layer and/or the high-index third layer comprise a bilayer of Si₃N₄/SnZnOₓ or SnZnOₓ/Si₃N₄.

18. The substrate as claimed in claim 2, wherein the multilayer (A) comprises a sequence of layers as below:
SnZnOₓ/SiO₂/Si₃N₄/SnZnOₓ/SiO₂
with Sn/Zn>1, expressed in atomic percent.

19. The substrate as claimed in claim 13, wherein the multilayer (A) comprises a sequence of layers as below:
SnZnOₓ/SiO₂/Si₃N₄/SnZnOₓ/SiO₂
with Sn/Zn>1, expressed in atomic percent.

20. The substrate as claimed in claim 2, wherein the multilayer (A) comprises a sequence of layers as below:
SnZnOₓ/SiO₂/SnZnOₓ/Si₃N₄/SiO₂
with Sn/Zn>1, expressed in atomic percent.
